(19) United States
(12) Patent Application Publication
(10) Pub. No.: US 2023/0123834 A1
(43) Pub. Date: Apr. 20, 2023

(54) EUV LITHOGRAPHY USING POLYMER CRYSTAL BASED RETICLE

(71) Applicant: Meta Platforms Technologies, LLC, Menlo Park, CA (US)

(72) Inventors: Pradip Sairam Pichumani, Bellevue, WA (US); Sandeep Rekhi, San Jose, CA (US); Thomas John Farrell Wallin, Redmond, WA (US)

(21) Appl. No.: 17/961,164

(22) Filed: Oct. 6, 2022

Related U.S. Application Data
(60) Provisional application No. 63/257,363, filed on Oct. 19, 2021.

(51) Int. Cl. G02F 1/137; G03F 1/22; G03F 1/36

(52) U.S. Cl. CPC G02F 1/137; G03F 1/22; G03F 1/36; G02F 2201/086; G02F 1/133385

(57) ABSTRACT

Embodiments of the present disclosure relate to a photomask. The photomask may include: a substrate; and one or more pixel units formed over the substrate. Each pixel unit may include: at least one polymer crystal element configured to interact with extreme ultraviolet (EUV) light based on an orientation of the polymer crystal element; and a plurality of electrodes configured to control the orientation of the polymer crystal element by applying voltage across the polymer crystal element. Each pixel unit is controlled by the respective plurality of electrodes independently, and the one or more pixel units generate a pattern for lithography upon exposure to the EUV light.

### CROSS-REFERENCE TO RELATED APPLICATIONS

This application claims the benefit of U.S. Provisional Application No. 63/257,363, filed Oct. 19, 2021, which is incorporated by reference in its entirety.

### FIELD OF THE INVENTION

The present disclosure generally relates to semiconductor manufacturing, and specifically relates to semiconductor manufacturing using extreme ultraviolet (EUV) lithography.

### BACKGROUND

EUV photomasks work by reflecting light. A typical EUV photomask (also referred to as a mask or reticle) is a complex stack of multilayered silicon and molybdenum. Photomasks are essential in generating the transistor and metal trace patterns on the wafer (e.g., silicon/III-V wafer). An advanced technology node like 14 nm or 7 nm may require about 50 to 100 photomasks, with each photomask typically costing between $350k and $750k. Thus, there is a significant investment needed from a technology development perspective to optimize the manufacturing process before moving into high volume. OPC (optical proximity correction) is a critical aspect of photomask development that optimizes the pattern on the mask depending on the light wavelength, diffraction compensation, etc. If done incorrectly, a redesign of the mask may be needed, and the cost and time taken to design and make new masks may be very high.

### SUMMARY

Embodiments of the present disclosure present a polymer crystal-based photomask which allows for the users to optimize the OPC (or other pattern related issues) during the lithography process. The photomask can be modified in-situ depending on the OPC, angle of EUV light used, and the type of pattern to be transferred on the wafer with photoresist.

In one aspect, the present disclosure relates to a photomask for EUV lithography. The photomask may include: a substrate; and one or more pixel units formed over the substrate. Each pixel unit may include: at least one polymer crystal element configured to interact with extreme ultraviolet (EUV) light based on an orientation of the polymer crystal element; and a plurality of electrodes configured to control the orientation of the polymer crystal element by applying voltage across the polymer crystal element. Each pixel unit is controlled by the respective plurality of electrodes independently, and the one or more pixel units generate a pattern for lithography upon exposure to the EUV light.

In another aspect, the present disclosure relates to a method for EUV lithography. The method may include receiving an instruction comprising a target photomask design; generating an OPC-adjusted mask pattern based on the photomask design; determining a pixel pattern based on the OPC-adjusted mask pattern; and configuring one or more pixel units of a polymer crystal-based photomask based on the determined pixel pattern. Each of the one or more pixel units may include at least one polymer crystal element configured to interact with extreme ultraviolet (EUV) light based on an orientation of the polymer crystal element; and a plurality of electrodes configured to control the orientation of the polymer crystal element by applying voltage across the polymer crystal element. Each pixel unit may be controlled by the respective plurality of electrodes independently, and the one or more pixel units generate the determined pixel pattern for lithography upon exposure to the EUV light.

### BRIEF DESCRIPTION OF THE DRAWINGS

FIG. 1 illustrates a diagram of a system for performing EUV lithography, in accordance with one or more embodiments.

FIGS. 2A-2C illustrate example mask patterns associated with an OPC process, in accordance with one or more embodiments.

FIG. 3 illustrates a cross-section view of a photomask, in accordance with one or more embodiments.

FIGS. 4A-4C illustrate cross-section views of the photomask with incident EUV light, in accordance with one or more embodiments.

FIGS. 5A-5B illustrate graphical representations of the photomask, in accordance with one or more embodiments.

FIG. 6 is a flowchart illustrating a process for generating a photomask for EUV lithography, in accordance with one or more embodiments.

FIG. 7 is a block diagram illustrating components of an example machine able to read instructions from a machine-readable medium and execute them in a processor, in accordance with one or more embodiments.

### DETAILED DESCRIPTION

The Figures (FIGS.) and the following description describe certain embodiments by way of illustration only. One skilled in the art will readily recognize from the following description that alternative embodiments of the structures and methods may be employed without departing from the principles described. Wherever practicable, similar or like reference numerals identify similar or identical structural elements or identify similar or like functionality. Where elements share a common numeral followed by a different letter, the elements are similar or identical. The numeral alone refers to any one or any combination of such elements.

Embodiments relate to an EUV photomask having a pixel array with polymer crystals (such as liquid crystals) that change from absorbance to reflectance of EUV light by changing the polymer crystals' orientation. The pixel array includes a plurality of pixel units that are controlled by electrodes. By using the pixel units that are able to selectively absorb or reflect the EUV light, the photomask that can be modified in-situ depending on OPC, angle of EUV light used, the type of pattern to be transferred on the wafer with photoresist, or some combination thereof. The proposed design would enable rapid prototyping without the need for a semiconductor mask house, as the polymer crystal based photomask may allow for OPC related issues to be rectified and corrected by adjusting the electrodes (e.g., thin film transistors) that control the orientations of the crystals, rather than undergoing a very expensive redesign of the mask. In addition, the need for multiple masks is reduced, since the polymer crystal-based photomask can be programmed to display different layers, enabling a reduction in time needed for mask swapping.

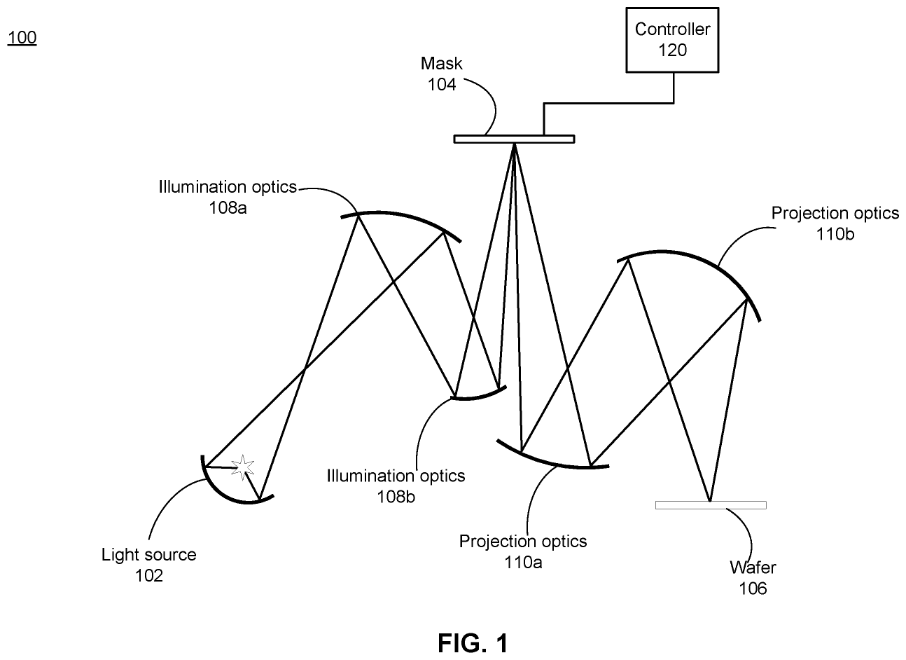

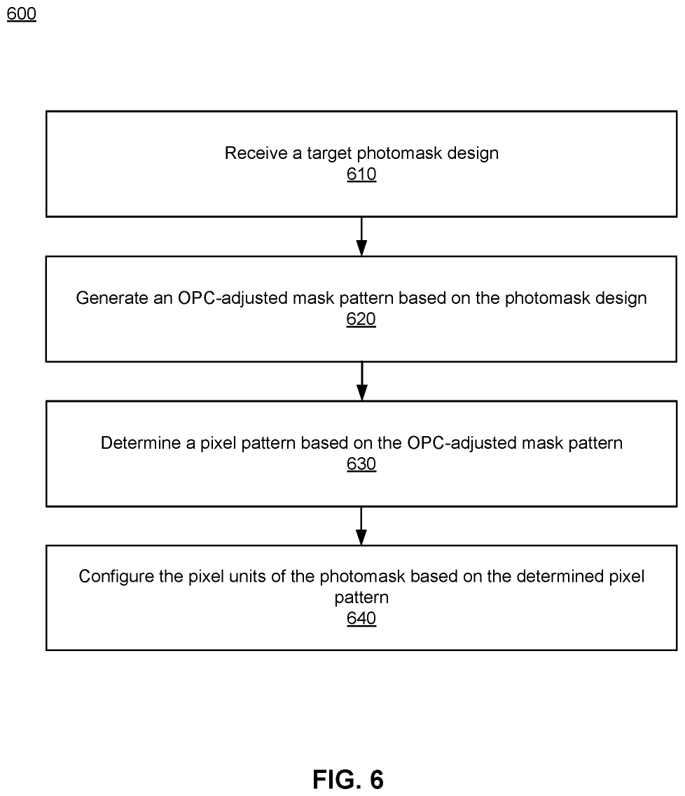

FIG. 1 illustrates a diagram of a system 100 for performing EUV lithography, in accordance with one or more embodiments. The system 100 may include a light source 102, a mask 104, a wafer 106, and a plurality of optical components. The plurality of optical component may include one or more collection/illumination optics 108a and 108b (collectively referred to as “illumination optics 108”) and one or more projection optics 110a and 110b (collectively referred to as “projection optics 110”). The light source 102 produces and transmits light through the one or more illumination optics 108 onto the mask 104. The light is in the EUV wavelength range, around 13.5 nm or in the range of 13.3-13.7 nm. The mask 104 is a reflective EUV photomask. In some embodiments, the mask 104 may have dimensions of 6″ by 6″ and be made of a multiplayer stack of molybdenum and silicon (Mo/Si), e.g., up to 40 layers. The projection optics 110 relay the pattern produced by the mask 104 onto the wafer 106, exposing resist on the wafer 106 according to the pattern. The exposed resist is then developed, producing patterned resist on the wafer 106. This is used to fabricate structures on the wafer, for example through deposition, doping, etching or other processes. Other types of lithography systems may also be used, including at other wavelengths including deep ultraviolet (DUV), using transmissive masks and/or optics, and using positive or negative resist. In some embodiments, the system 100 may further include a controller 120 for controlling the system 100 to perform the lithography process. The controller 120 may comprise a processor and a computer-readable storage medium. The controller 120 may receive an instruction comprising a target photomask design and generate a pixel pattern of the mask 104 for lithography. In some embodiments, the controller 120 is in communication with the mask 104 and can be used to dynamically adjust the mask pattern during the lithography process (e.g., as described below with regards to FIG. 6). Alternatively, the controller 120 may be a separate computer able to communicate with the system 100 that can provide control and/or configuration data to the EUV system 100.

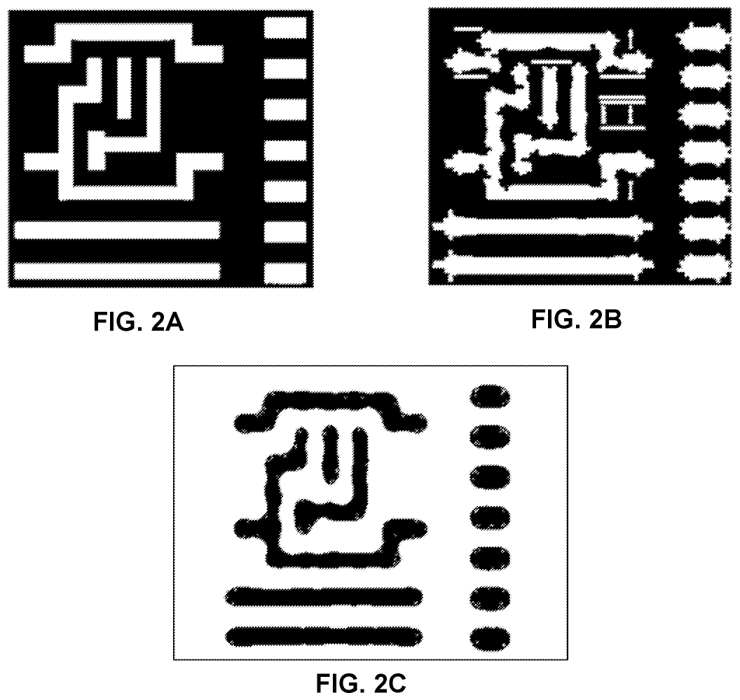

Optical Proximity Correction (OPC) is a photolithography enhancement technique commonly used to compensate for image errors due to diffraction or process effects. Due to the limitations of light to maintain the edge placement integrity of the original design, after processing, the projected images (i.e., the etched images on the wafer) may appear with irregularities such as line widths that are narrower or wider than designed. Such distortions, if not corrected for, may significantly alter the electrical properties of what was being fabricated. The OPC may correct these errors by changing the pattern on the photomask used for imaging, for example, by moving edges or adding extra polygons to the pattern written on the photomask. The objective is to reproduce on the wafer, as well as possible, the original layout drawn by the designer. During the OPC, design level elements are represented as a set of polygons that are carved onto a pixelated template which is the mask. The design of the mask can be adjusted based on the incident angle of light, diffraction, interference, divergence, wavelength, etc., to ensure the desired pattern is printed on the wafer (and quality degradation is addressed to avoid distortions). For example, FIGS. 2A-2C below illustrate example mask patterns associated with an OPC process, in accordance with one or more embodiments. FIG. 2A illustrates an example of a desired mask pattern, while FIG. 2B illustrates an OPC-adjusted mask pattern that is adjusted to account for the way light is reflected from the photomask, e.g., variations in angle in which light interacts with the photomask. FIG. 2C illustrates the resulting pattern by using the OPC-adjusted mask. The EUV light is projected by the mask onto a photoresist coating on the silicon wafer through an exposure process, where the exposed regions are then etched to form the target circuitry onto the silicon wafer. If the mask and/or the OPC is done incorrectly, distortions in the pattern are observed, resulting in malfunctioning of the circuit, e.g., rounded corners not adequately connecting to the underlying via, metal shorting, capacitance increase, and/or other issues.

For advanced lithography processes, a large number of EUV photomasks may be needed, e.g., for 5 nm technology nodes, approximately 50 EUV photomasks may be needed. In another example, multiple masks are required to generate a fin field-effect transistor (FinFET) or a back end of line (BEOL). Approximately 10 to 15 layers of metal lines form the logic trace for the 14 nm node. Different types of masks, such as, metallization mask, Ohmic contact mask, emitter diffusion mask, base diffusion mask, isolation diffusion mask, buried layer mask, etc., may be used. In some embodiments, each layer requires several masks to ensure the desired pattern is etched properly in the photoresist. In addition, defects in a photomask (e.g., due to amplitude defects, phase defects, OPC not done right) may require a photomask to be redesigned, further increasing costs. Embodiments of the present disclosure present a polymer crystal-based photomask which allows for the users to optimize the OPC during the lithography process. By controlling the electrical field applied to the polymer crystal elements in the photomask, the polymer crystals elements can change their orientations to reflect or absorb the incident EUV light. In this way, a desired pattern of photomask can be achieved and adjusted during the lithography process without need to create a new mask.

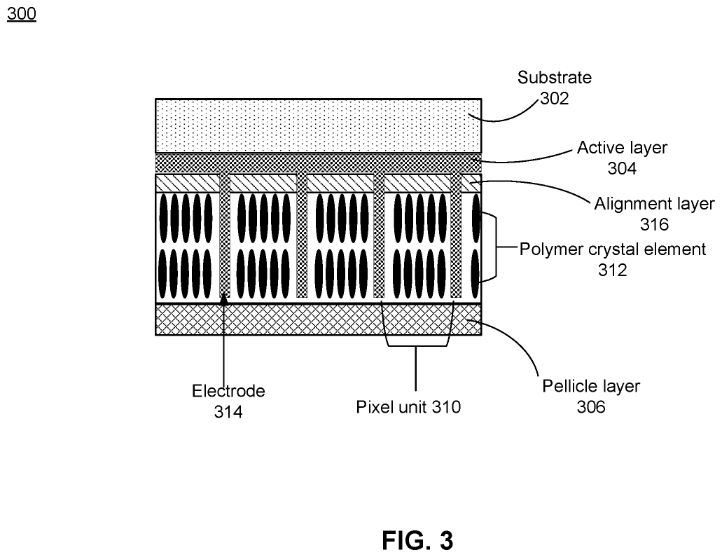

FIG. 3 illustrates a cross-section view of a photomask 300, in accordance with one or more embodiments. As shown in FIG. 3, the photomask 300 may include a substrate 302, an active layer 304, a pellicle layer 306, and one or more-pixel units 310. The substrate 302 may include silicon and provides a structural support for the photomask 300. The active layer 304 is formed between the substrate 302 and the one or more pixel units 310. The active layer 304 includes circuitries that are connected to each pixel unit 310.

Each pixel unit 310 may include at least one polymer crystal element 312 and a plurality of electrodes 314. In some embodiments, the plurality of electrodes 314 are configured to divide the photomask 300 into arrays and/or individual pixel units 310. The polymer crystal element 312 may be a liquid crystal element configured to interact with the EUV light based the orientation of the polymer crystal elements 312. In some embodiments, each pixel unit 310 may include a plurality of polymer crystal elements 312 that are formed in arrays and/or stacked on multiple layers. For example, the photomask 300 may include a plurality of layers of pixel units 310 stacking on the substrate 302, and each layer of pixel units 310 may be configured to interact with the EUV light at a different wavelength. The plurality of electrodes 314 are connected to the circuitries in the active layer 304. In some embodiments, the photomask 300 may further include one or more thin film transistors (TNTs) that are coupled with the electrodes 314 for controlling the orientations of the polymer crystal elements 312. The electrodes 314 are configured to be electrically connected to the polymer crystal elements 312 to control the orientations of the polymer crystal elements 312 by applying voltages. Each pixel unit 310 may be controlled by the respective plurality of electrodes 314 independently. Alternatively, adjacent pixel units 310 may share at least a portion of the electrodes 314, and some of the pixel units 310 may form into a plurality of groups. The pixel units 310 in each group may be controlled by the same electrodes 314 collectively.

In some embodiments, the polymer crystal element 312 may be a cholesteric liquid crystal (CLC) material. The CLC materials can be used for selective reflectance, where the reflectance change may be voltage induced (e.g., based on voltage applied at set angle relative to helical axes of the polymer). In some embodiments, other possible stimuli, such as heat, mechanical compression/shear, or another wavelength of light (e.g., for CLC materials containing azobenzene chiral dye) may be used to control the selective reflectance of the CLC material. In some embodiments, because the orientation of helical axes of the polymer crystals may affect how the polymer crystal elements reflect different wavelengths of light, multiple layers of CLCs may be used to interact with multiple different wavelengths.

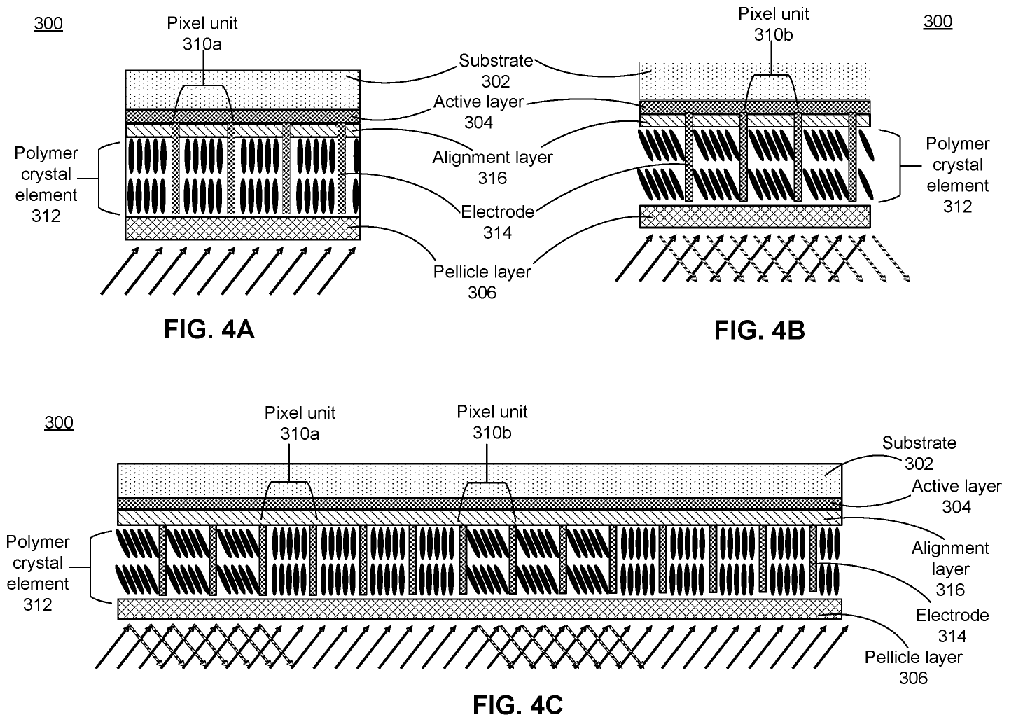

FIGS. 4A-4C illustrate cross-section views of the photomask with incident EUV light, in accordance with one or more embodiments. The orientations of the polymer crystal elements 312 may be changed by an electric field (e.g., induced by a small electric voltage) and thus the optical properties are affected accordingly. For example, the electrodes 314 in a pixel unit 310 may be configured to apply a voltage at a set angle relative to the helical axis of the polymer crystal elements 312 (e.g., liquid crystal) to control the orientation of the polymer. In one example, the electrodes 314 apply a first voltage to set the polymer crystal elements 312 in a first orientation so that the polymer crystal elements 312 absorb the incident EUV light, shown in the pixel unit 310a in FIG. 4A as an example. In another example, the electrodes 314 may apply a second voltage to set the polymer crystal elements in a second orientation so that the polymer crystal elements 312 reflect the incident EUV light, shown in the pixel unit 310b in FIG. 4B as an example. The polymer crystal elements 312 in the pixel units 310a and 310b are orientated based on the potential differences between the voltages of the electrodes 314, as shown in FIG. 4C, and the one or more pixel units 310a and 310b generate a pattern for lithography upon exposure to the EUV light.

The pellicle layer 306 may be a thin, transparent membrane that covers the photomask 300 during the lithography process. For example, the pellicle layer 306 may be made of polysilicon. The pellicle layer 306 is a dust cover, as it prevents particles and contaminates from falling on the photomask 300. The pellicle layer 306 is positioned on the pixel units 310 and exposed to the incident EUV light. In some embodiments, the pixel unit 310 may further include an alignment layer 316 that is configured to ensure correct mask orientation and check alignment accuracy.

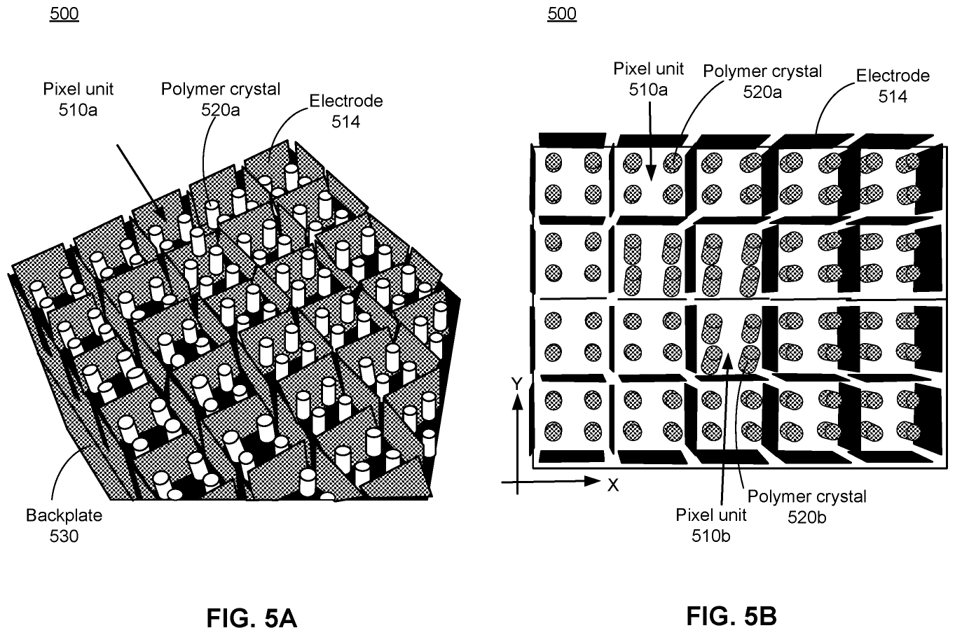

FIGS. 5A-5B illustrate graphical representations of the photomask 500, in accordance with one or more embodiments. The orientations of the polymer crystal elements 520 in different pixel units 510 may be different. Defining the substrate surface as the base plane, the polymer crystal elements 520a in the pixel units 510a are perpendicular to the base plane; and the polymer crystal elements 520b in the other pixel units 510b, are parallel (or at least have an acute angle) with the base plane. When the polymer crystal elements 520a are perpendicular to the base plane, defined as turned-off position, the polymer crystal elements 520a can absorb the incident EUV light. On the other hand, when the polymer crystal elements 520b are parallel to the base plane, defined as turned-on position, the polymer crystal elements 520b can reflect the incident EUV light. In some embodiments, the polymer crystal elements 520 in each pixel unit 510 are controlled by the same electrodes and thus orientated in the same direction. In this way, the separation of the photomask 500 into individual pixel unit 510 enables the photomask 500 to become a display with regions absorbing the EUV lights and regions reflecting the EUV light. As such, a user can correct the OPC during the photolithography process and achieve very high and accurate photolithography.

In some embodiments, the photomask 500 may include one or more backplates 530, as shown in FIG. 5A, to cool the polymer crystal elements 520a and 520b (collectively referred as to “polymer crystal elements 520”) in the pixel units 510a and 510b (collectively referred as to “pixel units 510”) respectively. The photomask 500 may be divided by one or more electrodes 514 into individual pixel units 510. The physical properties of the polymer crystal elements 520 may be affected by temperatures, as the thermal energy can cause the polymer crystal elements 520 to go through certain crystalline transitions, e.g., “resetting” the alignment of the polymer crystal elements 520 to a most entropically favorable orientation, which may interfere with the orientation control of the polymer crystal elements 520 by the electrodes. To mitigate the thermal interference, in some embodiments, the photomask 500 may comprise components for active temperature monitoring and control to improve performance and longevity. As shown in FIG. 5A, a backplate 530 located at the bottom of the photomask 500, is configured to perform active temperature management to maintain performance of the polymer crystal elements in the photomask 500.

In some embodiments, the photomask 500 may further include slider rails along X and Y axes. As shown in FIG. 5B, the X and Y axes are parallel to the base plane and perpendicular to each other. In some embodiments, a piezo based motor is connected to the slider rails. In some embodiments, the pixel units 510 of the photomask 500 may generate a pixelated imprint on the wafer (e.g., due to non-reflective regions corresponding to the electrodes between the pixels of the pixel array). With the slider rails and piezo based motor, the photomask 500 may rotate in the X-Y plane (e.g., translated along the +X direction, −X direction, +Y direction, and/or −Y direction) to reduce or mitigate the pixelated imprint.

FIG. 6 is a flowchart illustrating a process for generating a photomask for EUV lithography, in accordance with one or more embodiments. An EUV lithography system (e.g., system 100) may include a controller 120 (e.g., controller 120) for generating a photomask. The controller may comprise a processor and a computer-readable storage medium. As shown in FIG. 6, the controller receives 610 an instruction comprising a target photomask design (e.g., as shown in FIG. 2A) for performing an EUV lithography. To correct image errors that are likely to occur during the lithography process, the controller generates 620 an OPC-adjusted mask pattern (e.g., as shown in FIG. 2B) based on the target photomask design. The EUV lithography system includes a polymer crystal-based photomask, and the controller determines 630 a pixel pattern based on the OPC-adjusted mask pattern. The polymer crystal-based photomask may include one or more pixel units that comprise polymer crystal elements. The polymer crystal elements may interact the EUV light depending on their orientations. The orientations of the polymer crystal elements can be controlled by a plurality of electrodes. The electrodes may set the polymer crystal elements in a first orientation by applying a first voltage, and the polymer crystal elements absorb the EUV light; alternatively, the electrodes may set the polymer crystal elements in a second orientation by applying a second voltage, and the polymer crystal elements reflect the EUV light. Therefore, by controlling the electrodes, the EUV lithography system configures 640 the pixel units of the polymer crystal-based photomask based on the determined pixel pattern so that the polymer crystal-based photomask can generate a desired pattern for lithography upon exposure to the EUV light.

The photomask disclosed herein uses pixels of polymer material (e.g., liquid crystal) to enable rapid prototyping of test wafers and reduced time to manufacture, significantly reducing investment in mask development and mask house. For example, in some embodiments a single polymeric material-based photomask can be programmed to display different patterns, reducing expenses related to replacement or redesign of conventional photomasks. The disclosed photomask may also allow for fast optimization of layer thicknesses based on performance, where layer thicknesses in FinFETs and advanced technology nodes can be optimized without the need for expensive mask redesign. In some embodiments, micro lenses and waveguides can be prototyped, tested, and manufactured in significantly less time and reduced monetary investment.

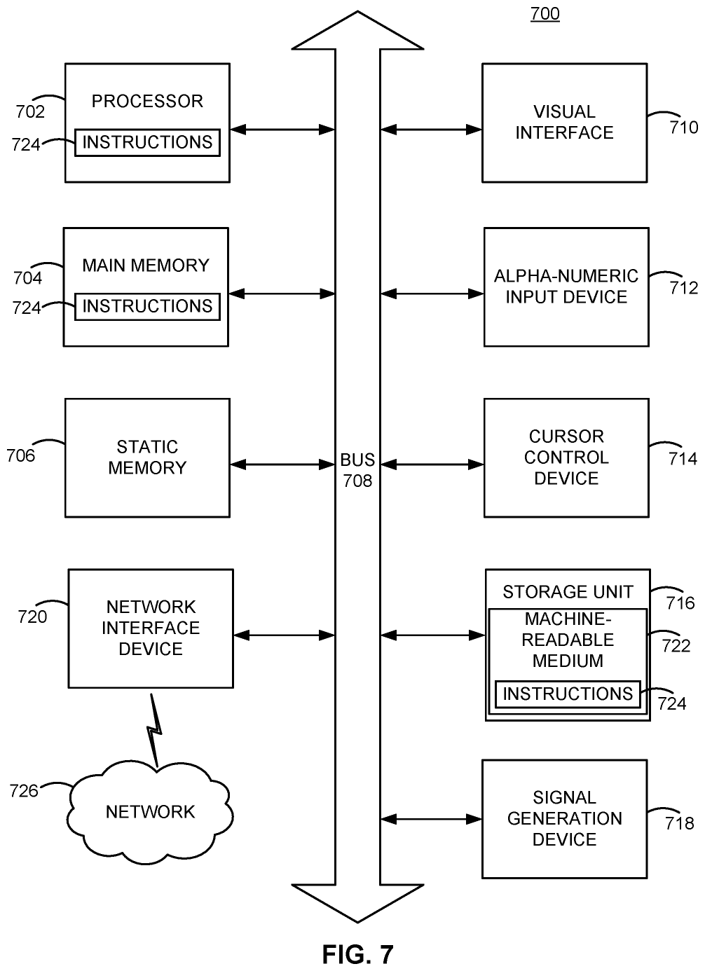

FIG. 7 is a block diagram illustrating components of an example machine able to read instructions from a machine-readable medium and execute them in a processor (e.g., controller 120). Specifically, FIG. 7 shows a diagrammatic representation of a machine in the example form of a computer system 700 within which program code (e.g., software) for causing the machine to perform any one or more of the methodologies discussed herein may be executed. The program code may be comprised of instructions 724 executable by one or more processors 702. In alternative embodiments, the machine operates as a standalone device or may be connected (e.g., networked) to other machines. In a networked deployment, the machine may operate in the capacity of a server machine or a client machine in a server-client network environment, or as a peer machine in a peer-to-peer (or distributed) network environment.

The machine may be a server computer, a client computer, a personal computer (PC), a tablet PC, a set-top box (STB), a personal digital assistant (PDA), a cellular telephone, a smartphone, a tablet, a web appliance, a network router, switch or bridge, or any machine capable of executing instructions 724 (sequential or otherwise) that specify actions to be taken by that machine. Further, while only a single machine is illustrated, the term “machine” shall also be taken to include any collection of machines that individually or jointly execute instructions 124 to perform any one or more of the methodologies discussed herein.

The example computer system 700 includes a processor 702 (e.g., a central processing unit (CPU), a graphics processing unit (GPU), a digital signal processor (DSP), one or more application specific integrated circuits (ASICs), one or more radio-frequency integrated circuits (RFICs), or any combination of these), a main memory 704, and a static memory 706, which are configured to communicate with each other via a bus 708. The computer system 700 may further include visual display interface 710. The visual interface may include a software driver that enables displaying user interfaces on a screen (or display). The visual interface may display user interfaces directly (e.g., on the screen) or indirectly on a surface, window, or the like (e.g., via a visual projection unit). For ease of discussion the visual interface may be described as a screen. The visual interface 710 may include or may interface with a touch enabled screen. The computer system 700 may also include alphanumeric input device 712 (e.g., a keyboard or touch screen keyboard), a cursor control device 714 (e.g., a mouse, a trackball, a joystick, a motion sensor, or other pointing instrument), a storage unit 716, a signal generation device 718 (e.g., a speaker), and a network interface device 720, which also are configured to communicate via the bus 708.

The storage unit 716 includes a machine-readable medium 722 on which is stored instructions 724 (e.g., software) embodying any one or more of the methodologies or functions described herein. The instructions 724 (e.g., software) may also reside, completely or at least partially, within the main memory 704 or within the processor 702 (e.g., within a processor's cache memory) during execution thereof by the computer system 700, the main memory 704 and the processor 702 also constituting machine-readable media. The instructions 724 (e.g., software) may be transmitted or received over a network 726 via the network interface device 720.

While machine-readable medium 722 is shown in an example embodiment to be a single medium, the term “machine-readable medium” should be taken to include a single medium or multiple media (e.g., a centralized or distributed database, or associated caches and servers) able to store instructions (e.g., instructions 724). The term “machine-readable medium” shall also be taken to include any medium that is capable of storing instructions (e.g., instructions 724) for execution by the machine and that cause the machine to perform any one or more of the methodologies disclosed herein. The term “machine-readable medium” includes, but not be limited to, data repositories in the form of solid-state memories, optical media, and magnetic media.

### Additional Configuration Information

The foregoing description of the embodiments has been presented for illustration; it is not intended to be exhaustive or to limit the patent rights to the precise forms disclosed. Persons skilled in the relevant art can appreciate that many modifications and variations are possible considering the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments may also relate to a product that is produced by a computing process described herein. Such a product may comprise information resulting from a computing process, where the information is stored on a non transitory, tangible computer readable storage medium and may include any embodiment of a computer program product or other data combination described herein.

Finally, the language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. A photomask, comprising:
a substrate; and
one or more pixel units formed over the substrate, each pixel unit comprising:
at least one polymer crystal element configured to interact with extreme ultraviolet (EUV) light based on an orientation of the polymer crystal element; and
a plurality of electrodes configured to control the orientation of the polymer crystal element by applying voltage across the polymer crystal element;
wherein each pixel unit is controlled by the respective plurality of electrodes independently, and the one or more pixel units generate a pattern for lithography upon exposure to the EUV light.

2. The photomask of claim 1, wherein the plurality of electrodes set the polymer crystal element in a first orientation by applying a first voltage, and the polymer crystal element is configured to absorb the EUV light in the first orientation.

3. The photomask of claim 1, wherein the plurality of electrodes set the polymer crystal element in a second orientation by applying a second voltage, and the polymer crystal element is configured to reflect the EUV light in the second orientation.

4. The photomask of claim 1, further comprising a pellicle layer covering the one or more pixel units to prevent contamination.

5. The photomask of claim 1, further comprising an active layer between the substrate and the one or more pixel units, wherein the active layer comprises circuitry that is connected to the plurality of electrodes.

6. The photomask of claim 1, wherein the polymer crystal element is a cholesteric liquid crystal (CLC) material.

7. The photomask of claim 1, further comprising a backplate configured to cool the one or more pixel units.

8. The photomask of claim 1, further comprising one or more slider rails and a motor configured to rotate the photomask.

9. The photomask of claim 1, further comprising a plurality of layers of pixel units stacking on the substrate, each layer of pixel units configured to interact with the EUV light at a different wavelength.

10. The photomask of claim 1, further comprising a temperature control component for monitoring and controlling a temperature of the photomask.

11. A method, comprising:
receiving an instruction comprising a target photomask design;
generating an OPC-adjusted mask pattern based on the photomask design;
determining a pixel pattern based on the OPC-adjusted mask pattern; and
configuring one or more pixel units of a polymer crystal-based photomask based on the determined pixel pattern, wherein each of the one or more pixel units comprises:
at least one polymer crystal element configured to interact with extreme ultraviolet (EUV) light based on an orientation of the polymer crystal element; and
a plurality of electrodes configured to control the orientation of the polymer crystal element by applying voltage across the polymer crystal element.

12. The method of claim 11, wherein configuring the one or more pixel units comprises applying a first voltage to set the polymer crystal element in a first orientation, causing the polymer crystal element to absorb the EUV light in the first orientation.

13. The method of claim 11, wherein configuring the one or more pixel units comprises applying a second voltage to set the polymer crystal element in a second orientation, causing the polymer crystal element to reflect the EUV light in the second orientation.

14. The method of claim 11, wherein the polymer crystal-based photomask further comprises:
a substrate which the one or more pixel units form over; and
a pellicle layer covering the one or more pixel units to prevent contamination.

15. The method of claim 14, wherein the polymer crystal-based photomask further comprises an active layer between the substrate and the one or more pixel units, and the active layer comprises circuitry that is connected to the plurality of electrodes.

16. The method of claim 14, wherein the polymer crystal-based photomask further comprises one or more slider rails and a motor configured to rotate the polymer crystal-based photomask.

17. The method of claim 14, wherein the polymer crystal-based photomask further comprises a plurality of layers of pixel units stacking on the substrate, each layer of pixel units configured to interact with the EUV light at a different wavelength.

18. The method of claim 11, wherein the polymer crystal element is a cholesteric liquid crystal (CLC) material.

19. The method of claim 11, wherein the polymer crystal-based photomask further comprises a backplate configured to cool the one or more pixel units.

20. The method of claim 11, wherein the polymer crystal-based photomask further comprises a temperature control component for monitoring and controlling a temperature of the photomask.
